(19) United States
(12) Patent Application Publication
(10) Pub. No.: US 2025/0140330 A1
(43) Pub. Date: May 1, 2025

(54) METHOD FOR ISOLATING FAULTY NAND TEMPERATURE SENSOR

(71) Applicant: WESTERN DIGITAL TECHNOLOGIES, INC., San Jose, CA (US)

(72) Inventors: VARUN SHARMA, Bangalore (IN); SOURABH SANKULE, Bangalore (IN); RAGHAVENDRA MYLARAPPA, Bangalore (IN); BHAVADIP SOLANKI, Bangalore (IN)

(73) Assignee: WESTERN DIGITAL TECHNOLOGIES, INC., San Jose, CA (US)

(21) Appl. No.: 18/383,730

(22) Filed: Oct. 25, 2023

(51) Int. Cl. G11C 29/12; G01K 15/00; G11C 7/24

(52) U.S. Cl. CPC G11C 29/12; G01K 15/007; G11C 7/24; G01K 2217/00

(57) ABSTRACT

A storage device identifies a die with a defective temperature sensor and excludes the die temperature from thermal calculations. The storage device includes a memory device with multiple dies. Each die includes a temperature sensor. A controller on the storage device executes a defective temperature sensor scheme to obtain a temperature for a first die in the memory device. The controller compares the first die temperature against a benchmark. The controller determines that the first die includes a defective temperature sensor if there is a temperature variance in the first die temperature and the benchmark and if the temperature variance is greater than a die temperature variation threshold.

### BACKGROUND

Non-volatile storage devices, such as solid-state drives (SSD) and the like, may include one or more memory devices for storing data and a controller for managing the internal operations of the storage device. A memory device may be divided into blocks, wherein multiple blocks may form a plane, one or more planes may form a die, and one or more dies may be included in a memory device. Each die may include a temperature sensor that may be used to monitor the thermal state of the die. The controller may monitor the thermal states of components of the storage device, including the dies in the memory device, to determine the overall thermal state of the storage device. When the temperature of the storage device exceeds a predefined operating temperature, the controller may execute a throttling mechanism by either reducing the frequency of operations carried out by components on the storage device or reducing the operational power of components on the storage device. If the throttling mechanism fails to bring the temperature of the storage device below a predefined thermal shutdown temperature, the controller may shut down the storage device to return the temperature of the storage device below the predefined operating temperature.

During manufacturing, an otherwise operable die may include a defective temperature sensor. When a die with a defective temperature sensor is included in a memory device coupled to the storage device and the controller uses the temperature readings from the die with a defective temperature sensor in its temperature calculations, the controller may calculate an incorrect temperature of the storage device, which may result in unnecessary thermal throttling or shutdown.

To reduce the chances of having dies with defective temperature sensors being in memory devices coupled to the storage device, during the manufacturing process, the composite temperature for the storage device may be tested to determine if the composite temperature for the storage device is below a predefined threshold. The composite temperature for the storage device may be the maximum temperature across the dies and other components of the storage device. If a temperature sensor on a die is defective, the composite temperature obtained for the storage device may also be faulty and may exceed the given threshold. When the composite temperature exceeds the given threshold, the storage device may be discarded. As such, a defective temperature sensor on a die may result in yield loss when the storage device is discarded. If the storage device is not discarded, the defective temperature sensor on one die may cause the storage device in use to enter an extreme thermal throttling state wherein the storage device may be shut down to reduce its temperature.

### SUMMARY

In some implementations, a storage device identifies a die with a defective temperature sensor on a memory device including multiple dies, wherein each die includes a temperature sensor. A controller on the storage device executes a defective temperature sensor scheme to obtain a temperature for a first die in the memory device. The controller compares the first die temperature against a benchmark. The controller determines that the first die includes a defective temperature sensor if there is a temperature variance in the first die temperature and the benchmark and if the temperature variance is greater than a die temperature variation threshold. The controller excludes the first die temperature from thermal calculations.

In some implementations, a method is provided for identifying a die with a defective temperature sensor. The method includes executing a defective temperature sensor scheme to obtain a temperature for a first die in the memory device and comparing the first die temperature against a benchmark. The method also includes determining that the first die includes a defective temperature sensor if there is a temperature variance in the first die temperature and the benchmark and if the temperature variance is greater than a die temperature variation threshold. The method further includes excluding the first die temperature from thermal calculations.

In some implementations, a method in a storage device is provided for identifying a die with a defective temperature sensor. The method includes executing at least one defective temperature sensor scheme to obtain a temperature for a first die in the memory device. The method also includes comparing the first die temperature against temperatures of other dies in the memory device; determining that temperatures of dies in the memory device are within a die temperature variation threshold and comparing a temperature of each die against an integrated circuit temperature or comparing a temperature of each die against a temperature of an internal temperature sensor; and obtaining information from a firmware to determine if the first die includes the defective temperature sensor. The method further includes determining that the first die includes a defective temperature sensor if a temperature variance between the first die temperature and the integrated circuit temperature or the temperature of the internal temperature sensor is greater than the die temperature variation threshold or if the information from the firmware indicates that the first die include the defective sensor. The method includes excluding the first die temperature from thermal calculations.

### BRIEF DESCRIPTION OF THE SEVERAL VIEWS OF THE DRAWINGS

FIG. 1 is a schematic block diagram of an example system in accordance with some implementations.

FIGS. 2A-2C are schematic block diagrams of example memory devices on which defective temperature sensor schemes may be executed in accordance with some implementations.

FIG. 3 is a flow diagram of an example process for determining when a temperature sensor on a die in a memory device is defective in accordance with some implementations.

FIG. 4 is a diagram of an example environment in which systems and/or methods described herein are implemented.

FIG. 5 is a diagram of example components of the host of FIG. 1.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of implementations of the present disclosure.

The apparatus and method components have been represented where appropriate by conventional symbols in the drawings, showing those specific details that are pertinent to understanding the implementations of the present disclosure so as not to obscure the disclosure with details that will be readily apparent to those of ordinary skill in the art.

### DETAILED DESCRIPTION OF THE INVENTION

The following detailed description of example implementations refers to the accompanying drawings. The same reference numbers in different drawings may identify the same or similar elements.

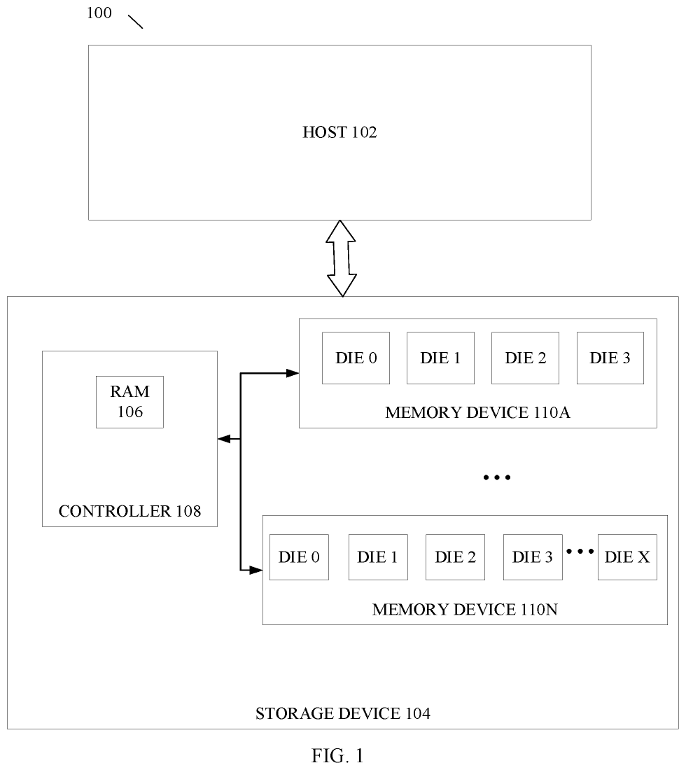

FIG. 1 is a schematic block diagram of an example system in accordance with some implementations. System 100 includes a host 102 and a storage device 104. Host 102 and storage device 104 may be in the same physical location as components on a single computing device or on different computing devices that are communicatively coupled. Storage device 104, in various embodiments, may be disposed in one or more different locations relative to the host 102. System 100 may include additional components (not shown in this figure for the sake of simplicity).

Storage device 104 may include a random-access memory (RAM) 106, a controller 108, and one or more non-volatile memory devices 110a-110n (referred to herein as the memory device(s) 110). Storage device 104 may be, for example, a solid-state drive (SSD), and the like. RAM 106 may be temporary storage such as a dynamic RAM (DRAM) that may be used in storage device 104.

Controller 108 may interface with host 102 and process foreground operations including instructions transmitted from host 102. For example, controller 108 may read data from and/or write to memory device 110 based on instructions received from host 102. Controller 108 may also execute background operations to manage resources on memory device 110. For example, controller 108 may monitor memory device 110 and may execute garbage collection and other relocation functions per internal relocation algorithms to refresh and/or relocate the data on memory device 110.

Memory device 110 may be flash based. For example, memory device 110 may be a NAND flash memory that may be used for storing host and control data over the operational life of memory device 110. Memory device 110 may include multiple dies (shown as Die 0-Die X). Memory device 110 may be included in storage device 104 or may be otherwise communicatively coupled to storage device 104.

During manufacturing, an otherwise functional die in memory device 110 may include a defective temperature sensor which may report an inaccurate die temperature and affect the overall temperature calculation associated with storage device 104. Controller 108 may monitor the temperature of components on storage device 104, including, for example, its temperature and the temperature of dies on memory devices 110. When storage device 104 operates with a thermal state in a normal operation zone, storage device 104 may provide its highest performance as guaranteed by a storage device's specification. High temperatures outside the normal operation zone may damage components on storage device 104 and/or degrade the performance of storage device 104. As such, controller 108 may implement one or more algorithms to maintain the thermal state of storage device 104 such that the temperature of storage device 104 may remain below a predefined normal operating temperature threshold. When the temperature of storage device 104 exceeds the normal operating temperature threshold, controller 108 may execute one or more thermal throttling algorithms to bring the temperature below the normal operating temperature threshold.

In some cases, when the temperature rises above the predefined normal operating temperature threshold, controller 108 may determine that storage device 104 is operating in a first thermal operation zone. The thermal throttling algorithm may attempt to control/reduce performance on storage device 104 to bring the temperature of storage device 104 from the first thermal operation zone below the normal operating temperature threshold.

If controller 108 is unsuccessful in reducing the temperature and the temperature rises above a predefined first zone temperature threshold, controller 108 may determine that storage device 104 is operating in a second thermal operation zone. The thermal throttling algorithm may similarly attempt to control/reduce performance on storage device 104 to bring the temperature of storage device 104 from the second thermal operation zone below the normal operating temperature threshold. If controller 108 is again unsuccessful in reducing the temperature and the temperature rises above a predefined thermal shutdown threshold, controller 108 may determine that storage device 104 is in a thermal shutdown zone. In the thermal shutdown zone, storage device 104 may move to a shutdown state with no active components. When the storage device is shut down, normal operations to host 102 may be denied.

To overcome cases where a defective temperature sensor on a die may affect the overall temperature calculation associated with storage device 104, controller 108 may execute one or more defective temperature sensor schemes to identify a die with a defective temperature sensor. In executing a defective temperature sensor scheme, controller 108 may obtain the temperature of a first die, compare the first die temperature to a benchmark, and determine that the first die includes a defective temperature sensor if there is a temperature variance in the first die temperature and the benchmark and if the temperature variance is greater than a configurable die temperature variation threshold. The die temperature variation threshold may be configured based on hardware value(s).

When a die with a defective temperature sensor is identified, controller 108 may exclude the temperature reading of the die from its thermal calculations including, for example, thermal throttling calculations, thermal shut down calculations, and/or composite temperature calculations. Controller 108 may execute one or more defective temperature sensor schemes, for example, before performing thermal calculations, during initialization of storage device 104, and/or at other predefined times.

In the first defective temperature sensor scheme, controller 108 may compare the temperature of a first die against the temperature of other dies in memory device 110 (for example, one benchmark). Controller may determine if there is a temperature variance in the temperature of the first die as compared to the temperature of each of the other dies in memory device 110 and if the temperature variance is greater than the die temperature variation threshold. If the temperature variance between the temperature of the first die and the temperatures of one or more of the other dies in memory device 110 is greater than the die temperature variation threshold, controller 108 may determine that the first die includes a defective temperature sensor and may exclude the temperature of that die from its thermal calculations.

Consider an example where controller 108 may compare the temperature of Die 0 in memory device 110A against the temperatures of Dies 1-3 in memory device 110A. If the temperature of Die 0 is 45 degrees Celsius (C), the temperature of Die 1 is 56C, the temperature of Die 2 is 54C, the temperature of Die 3 is 55C, and if the die temperature variation threshold is 5C, controller 108 may determine that Die 0 has a defective temperature sensor as the temperature of Die 0 varies from the temperatures of Dies 1-3 by 11C, 9C, and 10C, respectively, and the temperature variances of Dies 1-3 are less than the die temperature variation threshold.

In a second defective temperature sensor scheme, controller 108 may determine if the temperatures of two or more dies in memory device 110 are within the die temperature variation threshold. Controller 108 may also determine that no single die has a temperature variance outside the die temperature variation threshold when comparing that die temperature to the temperatures of other dies on memory device 110. Controller 108 may compare the temperature of each die against an application-specific integrated circuit (ASIC) temperature (for example, another benchmark). Controller 108 may determine if the temperature variation between the temperature of a die and the ASIC temperature is greater than the die temperature variation threshold. If the temperature variance between the die temperature and the ASIC temperature is greater than the die temperature variation threshold, controller 108 may determine that the die includes a defective temperature sensor and may exclude the temperature of that die from its thermal calculations.

Consider an example where the temperature of Die 0 is 45C, the temperature of Die 1 is 46C, the temperature of Die 2 is 54C, the temperature of Die 3 is 55C, and the die temperature variation threshold is 5C. Controller 108 may determine that the temperature variance of Die 0 and Die 1 is within 5C (i.e., the die temperature variation threshold) and that the temperature variance of Die 2 and Die 3 is within 5C. Controller 108 may compare the temperature of each die against the ASIC temperature and determine if the temperature variation between the temperature of a die and the ASIC temperature is greater than the die temperature variation threshold If the ASIC temperature is 53C, the variance of the temperature of Die 0 and the ASIC temperature will be 8C, the variance of the temperature of Die 1 and the ASIC temperature will be 7C, the variance of the temperature of Die 2 and the ASIC temperature will be 1C, and the variance of the temperature of Die 3 and the ASIC temperature will be 2C. As the variance of the temperatures of Die 0 and Die 1 and the ASIC temperature is greater than 5C, controller 108 may determine that Die 0 and Die 1 have defective temperature sensors and controller 108 may not include the temperatures of Die 0 and Die 1 in its thermal calculations.

In a third defective temperature sensor scheme, controller 108 may determine if the temperatures of two or more dies in memory device 110 are within the die temperature variation threshold. Controller 108 may also determine that no single die has a temperature variance outside the die temperature variation threshold when comparing that die temperature to the temperatures of other dies on memory device 110. Controller 108 may compare the temperature of each die against a temperature obtained from an internal temperature sensor (for example, another benchmark) placed in storage device 104. Controller 108 may determine if the temperature variation between the die temperature and the temperature of the internal temperature sensor is greater than the die temperature variation threshold, and if it is, controller 108 may determine that the die includes a defective temperature sensor and may exclude the temperature of that die from its thermal calculations. The internal temperature sensor may be set to provide the ambient temperature of storage device 104.

Using the example where the temperature of Die 0 is 45 C, the temperature of Die 1 is 46C, the temperature of Die 2 is 54C, the temperature of Die 3 is 55C, and the die temperature variation threshold is 5C, the temperature of Die 0 is within 5C of the temperature of Die 1 and the temperature of Die 2 is within 5C of the temperature of Die 3. If the temperature of the internal temperature sensor is 54C, the variance of the temperature of Die 0 and the internal temperature will be 9C, the variance of the temperature of Die 1 and the internal temperature will be 8C, the variance of the temperature of Die 2 and the internal temperature will be 0C, and the variance of the temperature of Die 3 and the internal temperature will be 1C. As the variance of the temperatures of Die 0 and Die 1 and the temperature of the internal temperature sensor is greater than 5C, controller 108 may determine that Die 0 and Die 1 have defective temperature sensors and controller 108 may not include the temperatures of Die 0 and Die 1 in its thermal calculations.

When the temperature sensor on a die is determined to be faulty during manufacturing and testing, firmware on storage device 104 may be updated to note that the temperature sensor of the die is defective. In a fourth defective temperature sensor scheme, controller 108 may check the firmware to determine if the temperature sensor on a die is noted as being defective. Controller 108 may not include the temperature reading of a die noted to a defective temperature sensor in its thermal calculations. A defective temperature sensor may likely have a permanent defect. In some cases, once controller 108 determines that a die includes a defective temperature sensor, controller 108 may note the defect and may not run further defective temperature sensor schemes on the die noted with the defective temperature sensor. As such, once the temperature sensor on a die is noted as being defective, controller 108 may not include temperature readings from that temperature sensor during its thermal calculations.

Storage device 104 may perform these processes based on a processor, for example, controller 108 executing software instructions stored by a non-transitory computer-readable medium. As used herein, the term “computer-readable medium” refers to a non-transitory memory device. Software instructions may be read into the memory device from another computer-readable medium or from another device. When executed, software instructions stored in the memory device may cause controller 108 to perform one or more processes described herein. Additionally, or alternatively, hardware circuitry may be used in place of or in combination with software instructions to perform one or more processes described herein. Thus, implementations described herein are not limited to any specific combination of hardware circuitry and software.

The number and arrangement of components shown in FIG. 1 are provided as an example. In practice, host 102 and/or storage device 104 may include additional components, fewer components, different components, or differently arranged components than those shown in FIG. 1. Additionally, or alternatively, a set of components (e.g., one or more components) of host 102 and/or storage device 104 may perform one or more functions described as being performed by another set of components of host 102 and/or storage device 104.

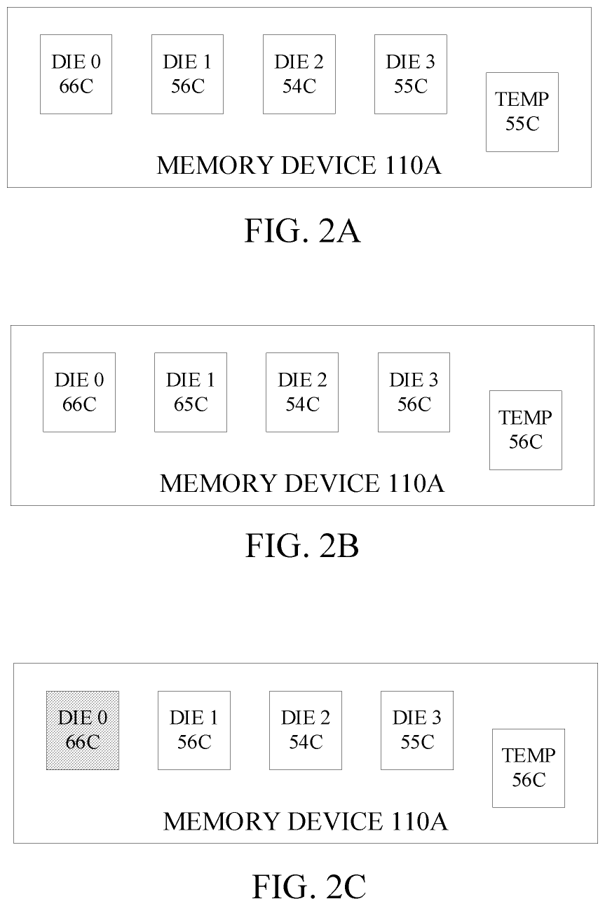

FIGS. 2A-2C are schematic block diagrams of example memory devices on which defective temperature sensor schemes may be executed in accordance with some implementations. FIG. 2A shows memory device 110A including four dies (i.e., Die 0-Die 3). The temperature reading of Die 0 may be 66C, the temperature reading of Die 1 may be 56C, the temperature reading of Die 2 may be 54C, and the temperature reading of Die 3 may be 55C. Controller 108 may configure the die temperature variation threshold to be 5C. If controller 108 executes the first defective temperature sensor scheme on memory device 110A prior to performing its thermal calculations, controller 108 may determine that the temperature variation between Die 0 and Die 1 is 10C, the temperature variation between Die 0 and Die 2 is 12C, and the temperature variation between Die 0 and Die 3 is 11C. Controller 108 may also determine that the temperatures variations between Die 1, Die 2, and Die 3 are within 5C. Controller 108 may thus determine that the temperature sensor on Die 0 is defective and may not include the temperature reading from Die 0 in its thermal calculations. If controller 108 calculates the temperature of memory device 110A using the average die temperatures, controller 108 may determine that the temperature (TEMP) of memory device 110A is 55C.

FIG. 2B shows an example where the of the temperature reading of Die 0 may be 66C, temperature reading of Die 1 may be 65C, the temperature reading of Die 2 may be 54C, and the temperature reading of Die 3 may be 56C. Controller 108 may configure the die temperature variation threshold to be 5C. If controller 108 executes the first defective temperature sensor scheme on memory device 110A prior to performing thermal calculations, controller 108 may determine that the temperature variation between Die 0 and Die 1 is 1C (i.e., within the die temperature variation threshold) and the temperature variation between Die 2 and Die 3 is also 2C (i.e., within the die temperature variation threshold). Controller 108 may thus determine that no single die is outside of the die temperature variation threshold with respect to all other dies on memory device 110A. Accordingly, controller 108 may determine the first defective temperature sensor scheme may not be an inappropriate defective temperature sensor scheme for finding dies with defective temperature sensors in this configuration.

Controller 108 may execute the second defective temperature sensor scheme or the third defective temperature sensor scheme, wherein controller 108 may compare the temperature of each die against an ASIC temperature or a temperature from an internal temperature sensor on storage device 104. If the ASIC temperature or internal temperature is 56C, controller may determine that the temperature variation between Die 0 and the ASIC temperature or internal temperature is 10C, the temperature variation between Die 1 and the ASIC temperature or internal temperature is 9C, the temperature variation between Die 2 and the ASIC temperature or internal temperature is 2C, and the temperature variation between Die 3 and the ASIC temperature or internal temperature is OC. Controller 108 may thus determine that the temperature sensors on Die 0 and Die 1 may be defective and may not include the temperature readings from Die 0 and Die 1 in its thermal calculations. If controller 108 calculates the temperature of memory device 110A using the highest die temperature, controller 108 may determine that the temperature (TEMP) of memory device 110A is 56C.

FIG. 2C shows a block diagram wherein controller 108 uses a fourth defective temperature sensor scheme to determine the temperature of memory device 110A. Controller 108 may check firmware on storage device 104 to determine if the temperature sensor of a die on memory device 110A is noted as defective. If, for example, during testing at the manufacturing stage the temperature sensor on Die 0 was noted as being defective or if during execution of a defective temperature sensor scheme controller 108 updated a firmware to note that Die 0 includes a defective temperature sensor, when controller 108 obtains an indication of Die 0 defect from the firmware, controller 108 may not include the temperature reading from Die 0 in its thermal calculations. If controller 108 calculates the temperature of memory device 110A using the highest die temperature, controller 108 may determine that the temperature (TEMP) of memory device 110A is 56C. As indicated above FIGS. 2A-2C are provided as examples. Other examples may differ from what is described in FIGS. 2A-2C.

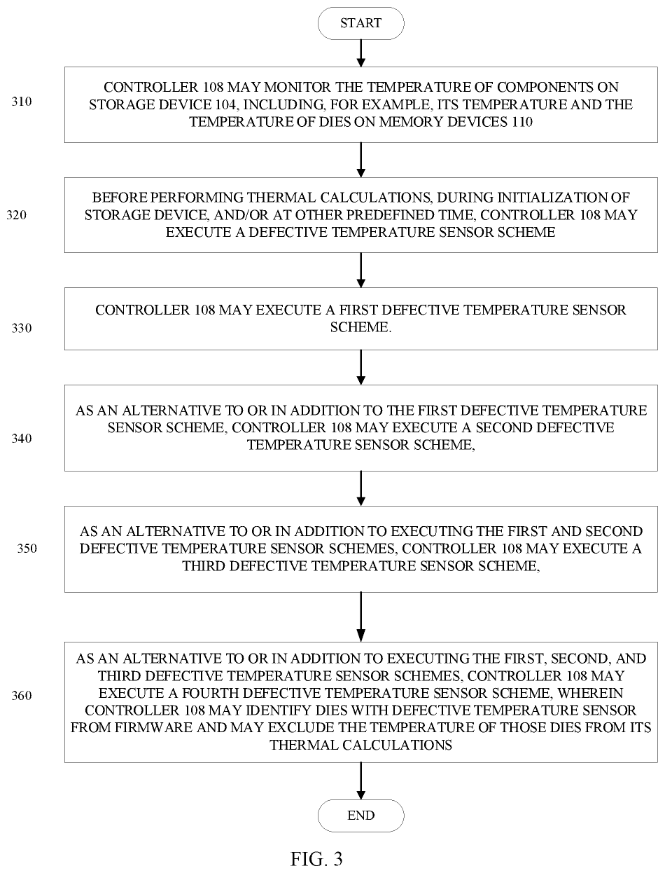

FIG. 3 is a flow diagram of an example process for determining when a temperature sensor on a die in a memory device is defective in accordance with some implementations. At 310, controller 108 may monitor the temperature of components on storage device 104, including, for example, its temperature and the temperature of dies on memory devices 110. At 320, before performing thermal calculations, during initialization of storage device, and/or at other predefined time, controller 108 may execute a defective temperature sensor scheme.

At 330, controller 108 may execute a first defective temperature sensor scheme. As part of the first defective temperature sensor scheme, controller 108 may compare the temperature of a die to the temperature of other dies in memory device 110 and if there is a temperature variance between a first die and the remaining dies memory device 110 that is greater than a die temperature variation threshold, controller 108 may determine that the first dies includes a defective temperature sensor and may exclude the temperature of that die from its thermal calculations.

At 340, as an alternative to or in addition to the first defective temperature sensor scheme, controller 108 may execute a second defective temperature sensor scheme. As part of the second defective temperature sensor scheme, controller 108 may determine that the temperatures of the dies in memory device 110 are within the die temperature variation threshold and controller 108 may compare the temperature of each die against an ASIC temperature. If there is a temperature variance between a die temperature and the ASIC temperature that is greater than the die temperature variation threshold, controller 108 may determine that the die includes a defective temperature sensor and may exclude the temperature of that die from its thermal calculations.

At 350, as an alternative to or in addition to executing the first and second defective temperature sensor schemes, controller 108 may execute a third defective temperature sensor scheme. As part of the third defective temperature sensor scheme, controller 108 may determine that the temperatures of the dies in memory device 110 are within the die temperature variation threshold and controller 108 may compare the temperature of each die against an internal temperature. If there is a temperature variance between a die temperature and the internal temperature that is greater than the die temperature variation threshold, controller 108 may determine that the die includes a defective temperature sensor and may exclude the temperature of that die from its thermal calculations.

At 360, as an alternative to or in addition to executing the first, second, and third defective temperature sensor schemes, controller 108 may execute a fourth defective temperature sensor scheme, wherein controller 108 may identify dies with defective temperature sensor from firmware and may exclude the temperature of those dies from its thermal calculations. As indicated above FIG. 3 is provided as an example. Other examples may differ from what is described in FIG. 3.

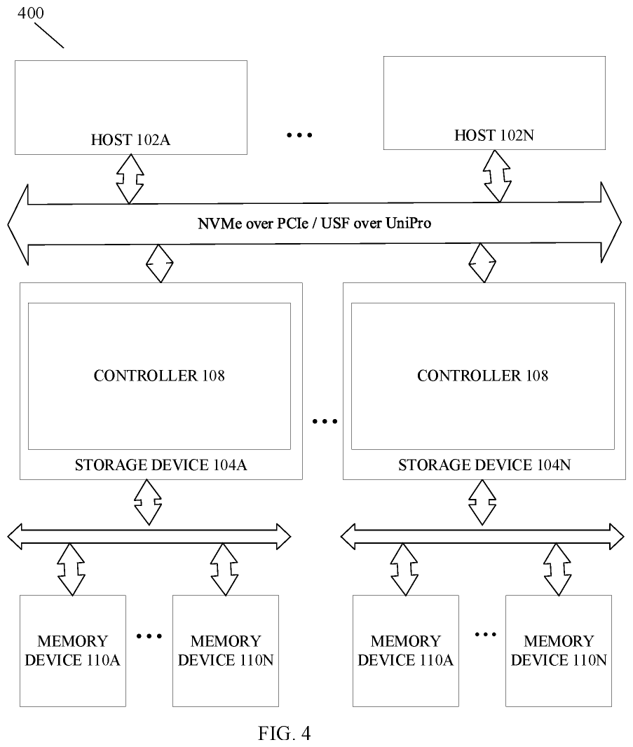

FIG. 4 is a diagram of an example environment in which systems and/or methods described herein are implemented. As shown in FIG. 4, Environment 400 may include hosts 102-102n (referred to herein as host(s) 102), and storage devices 104a-104n (referred to herein as storage device(s) 104).

Storage device 104 may include a controller 108 to manage the resources on storage device 104. Controller 108 may execute one or more defective temperature sensor schemes to identify dies on memory device 110 with defective sensors and to eliminate temperature readings from defective sensors from thermal calculations. Hosts 102 and storage devices 104 may communicate via a Serial AT attachment (SATA) interface, Non-Volatile Memory Express (NVMe) over peripheral component interconnect express (PCI Express or PCIe) interface, the Universal Flash Storage (UFS) over Unipro, or the like.

Devices of Environment 400 may interconnect via wired connections, wireless connections, or a combination of wired and wireless connections. For example, the network of FIG. 4 may include a cellular network (e.g., a long-term evolution (LTE) network, a code division multiple access (CDMA) network, a 3G network, a 4G network, a 5G network, another type of next-generation network, and/or the like), a public land mobile network (PLMN), a local area network (LAN), a wide area network (WAN), a metropolitan area network (MAN), a telephone network (e.g., the Public Switched Telephone Network (PSTN)), a private network, an ad hoc network, an intranet, the Internet, a fiber optic-based network, a cloud computing network, or the like, and/or a combination of these or other types of networks.

The number and arrangement of devices and networks shown in FIG. 4 are provided as an example. In practice, there may be additional devices and/or networks, fewer devices and/or networks, different devices and/or networks, or differently arranged devices and/or networks than those shown in FIG. 4. Furthermore, two or more devices shown in FIG. 4 may be implemented within a single device, or a single device shown in FIG. 4 may be implemented as multiple, distributed devices. Additionally, or alternatively, a set of devices (e.g., one or more devices) of Environment 400 may perform one or more functions described as being performed by another set of devices of Environment 400.

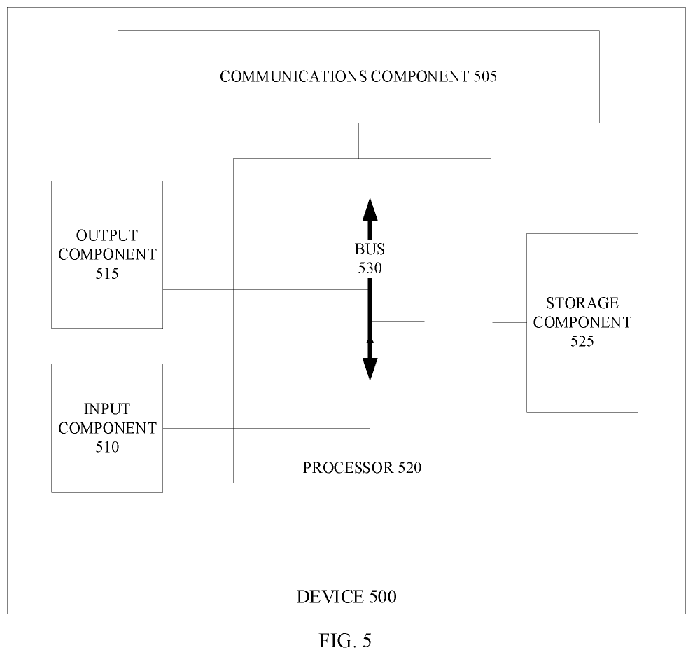

FIG. 5 is a diagram of example components of one or more devices of FIG. 1. In some implementations, host 102 may include one or more devices 500 and/or one or more components of device 500. Device 500 may include, for example, a communications component 505, an input component 510, an output component 515, a processor 520, a storage component 525, and a bus 530. Bus 530 may include components that enable communication among multiple components of device 500, wherein components of device 500 may be coupled to be in communication with other components of device 500 via bus 530.

Input component 510 may include components that permit device 500 to receive information via user input (e.g., keypad, a keyboard, a mouse, a pointing device, a microphone, and/or a display screen), and/or components that permit device 500 to determine the location or other sensor information (e.g., an accelerometer, a gyroscope, an actuator, another type of positional or environmental sensor). Output component 515 may include components that provide output information from device 500 (e.g., a speaker, display screen, and/or the like). Input component 510 and output component 515 may also be coupled to be in communication with processor 520.

Processor 520 may be a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some implementations, processor 520 may include one or more processors capable of being programmed to perform a function. Processor 520 may be implemented in hardware, firmware, and/or a combination of hardware and software.

Storage component 525 may include one or more memory devices, such as random-access memory (RAM), read-only memory (ROM), and/or another type of dynamic or static storage device (e.g., a flash memory, a magnetic memory, and/or optical memory) that stores information and/or instructions for use by processor 520. A memory device may include memory space within a single physical storage device or memory space spread across multiple physical storage devices. Storage component 525 may also store information and/or software related to the operation and use of device 500. For example, storage component 525 may include a hard disk (e.g., a magnetic disk, an optical disk, and/or a magneto-optic disk), a solid-state drive (SSD), a compact disc (CD), a digital versatile disc (DVD), a floppy disk, a cartridge, a magnetic tape, and/or another type of non-transitory computer-readable medium, along with a corresponding drive.

Communications component 505 may include a transceiver-like component that enables device 500 to communicate with other devices, such as via a wired connection, a wireless connection, or a combination of wired and wireless connections. The communications component 505 may permit device 500 to receive information from another device and/or provide information to another device. For example, communications component 505 may include an Ethernet interface, an optical interface, a coaxial interface, an infrared interface, a radio frequency (RF) interface, a universal serial bus (USB) interface, a Wi-Fi interface, and/or a cellular network interface that may be configurable to communicate with network components, and other user equipment within its communication range. Communications component 505 may also include one or more broadband and/or narrowband transceivers and/or other similar types of wireless transceiver configurable to communicate via a wireless network for infrastructure communications. Communications component 505 may also include one or more local area network or personal area network transceivers, such as a Wi-Fi transceiver or a Bluetooth transceiver.

Device 500 may perform one or more processes described herein. For example, device 500 may perform these processes based on processor 520 executing software instructions stored by a non-transitory computer-readable medium, such as storage component 525. As used herein, the term “computer-readable medium” refers to a non-transitory memory device. Software instructions may be read into storage component 525 from another computer-readable medium or from another device via communications component 505. When executed, software instructions stored in storage component 525 may cause processor 520 to perform one or more processes described herein. Additionally, or alternatively, hardware circuitry may be used in place of or in combination with software instructions to perform one or more processes described herein. Thus, implementations described herein are not limited to any specific combination of hardware circuitry and software.

The number and arrangement of components shown in FIG. 5 are provided as an example. In practice, device 500 may include additional components, fewer components, different components, or differently arranged components than those shown in FIG. 5. Additionally, or alternatively, a set of components (e.g., one or more components) of device 500 may perform one or more functions described as being performed by another set of components of device 500.

The foregoing disclosure provides illustrative and descriptive implementations but is not intended to be exhaustive or to limit the implementations to the precise form disclosed herein. One of ordinary skill in the art will appreciate that various modifications and changes can be made without departing from the scope of the present disclosure as set forth in the claims below. Accordingly, the specification and figures are to be regarded in an illustrative rather than a restrictive sense, and all such modifications are intended to be included within the scope of present teachings.

As used herein, the term “component” is intended to be broadly construed as hardware, firmware, and/or a combination of hardware and software. It will be apparent that systems and/or methods described herein may be implemented in different forms of hardware, firmware, and/or a combination of hardware and software.

Even though particular combinations of features are recited in the claims and/or disclosed in the specification, these combinations are not intended to limit the disclosure of various implementations In fact, many of these features may be combined in ways not specifically recited in the claims and/or disclosed in the specification Although each dependent claim listed below may directly depend on only one claim, the disclosure of various implementations includes each dependent claim in combination with every other claim in the claim set.

No element, act, or instruction used herein should be construed as critical or essential unless explicitly described as such. Also, as used herein, the articles “a” and “an” are intended to include one or more items and may be used interchangeably with “one or more.” Furthermore, as used herein, the term “set” is intended to include one or more items (e.g., related items, unrelated items, a combination of related items, unrelated items, and/or the like), and may be used interchangeably with “one or more” The term “only one” or similar language is used where only one item is intended. Further, the phrase “based on” is intended to mean “based, at least in part, on” unless explicitly stated otherwise.

Moreover, in this document, relational terms such as first and second, top and bottom, and the like, may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, or “contains . . . a” does not, without more constraints, preclude the existence of additional identical elements in the process, method, article, or apparatus that comprises, has, includes, contains the element. The terms “substantially”, “essentially”, “approximately”, “about” or any other version thereof, are defined as being close to as understood by one of ordinary skill in the art, and in one non-limiting implementation, the term is defined to be within 10%, in another implementation within 5%, in another implementation within 1% and in another implementation within 0.5%. The term “coupled” as used herein is defined as connected, although not necessarily directly and not necessarily mechanically. A device or structure that is “configured” in a certain way is configured in at least that way but may also be configured in ways that are not listed.

We claim:

1. A storage device to identify a die with a defective temperature sensor, the storage device comprises:
a memory device including multiple dies, wherein each die includes a temperature sensor; and
a controller to execute a defective temperature sensor scheme and to at least one of:
obtain a temperature for a first die in the memory device, compare the first die temperature against a benchmark, determine that the first die includes a defective temperature sensor if there is a temperature variance in the first die temperature and the benchmark and if the temperature variance is greater than a die temperature variation threshold; and
obtain information from a firmware to determine if the first die includes the defective temperature sensor; and
exclude the first die temperature from thermal calculations.

2. The storage device of claim 1, wherein the controller executes the defective temperature sensor scheme one of before performing thermal calculations, during initialization of the storage device, and at other predefined times.

3. The storage device of claim 1, wherein the die temperature variation threshold is a configurable value based on at least one hardware value.

4. The storage device of claim 1, wherein the thermal calculations include at least one of thermal throttling calculations, thermal shut down calculations, and composite temperature calculations.

5. The storage device of claim 1, wherein the defective temperature sensor scheme includes a first defective temperature sensor scheme wherein the controller:
compares the first die temperature against temperatures of other dies in the memory device,
determines that there is a temperature variance between the first die temperature and the temperatures of the other dies in the memory device and that the temperature variance is greater than the die temperature variation threshold; and
determines that the first die includes the defective temperature sensor.

6. The storage device of claim 1, wherein the defective temperature sensor scheme includes a second defective temperature sensor scheme wherein the controller:
determines that temperatures of dies in the memory device are within the die temperature variation threshold,
compares a temperature of each die against an integrated circuit temperature,
determines that there is a temperature variance between a die temperature and the integrated circuit temperature, and that the temperature variance is greater than the die temperature variation threshold; and
determines that a die with a temperature variance that is greater than the die temperature variation threshold includes the defective temperature sensor.

7. The storage device of claim 6, wherein the controller determines that no single die on the memory device has a temperature variance outside the die temperature variation threshold when compared to die temperature of another die on the memory device.

8. The storage device of claim 1, wherein the defective temperature sensor scheme includes a third defective temperature sensor scheme wherein the controller:
determines that temperatures of dies in the memory device are within the die temperature variation threshold,
compares a temperature of each die against a temperature of an internal temperature sensor,
determines that there is a temperature variance between a die temperature and the temperature of an internal temperature sensor, and that the temperature variance is greater than the die temperature variation threshold; and
determines that a die with a temperature variance that is greater than the die temperature variation threshold includes the defective temperature sensor.

9. The storage device of claim 8, wherein the controller determines that no single die on the memory device has a temperature variance outside the die temperature variation threshold when compared to die temperature of another die on the memory device.

10. The storage device of claim 8, wherein the internal temperature sensor is set to provide an ambient temperature of the storage device.

11. The storage device of claim 1, wherein the defective temperature sensor scheme includes a fourth defective temperature sensor scheme wherein the controller checks a firmware to determine if the first die includes the defective temperature sensor.

12. A method in a storage device for identifying a die with a defective temperature sensor, the storage device includes a controller for executing the method comprising:
executing a defective temperature sensor scheme to obtain a temperature for a first die in a memory device;
at least one of:
comparing the first die temperature against a benchmark and determining that the first die includes a defective temperature sensor if there is a temperature variance in the first die temperature and the benchmark and if the temperature variance is greater than a die temperature variation threshold; and
obtaining information from a firmware to determine if the first die includes the defective temperature sensor; and
excluding the first die temperature from thermal calculations.

13. The method of claim 12, further comprising executing the defective temperature sensor scheme one of before performing thermal calculations, during initialization of the storage device, and at other predefined times.

14. The method of claim 12, further comprising executing a first defective temperature sensor scheme wherein:
the comparing comprises comparing the first die temperature against temperatures of other dies in the memory device, and
the determining comprises determining that there is a temperature variance between the first die temperature and the temperatures of the other dies in the memory device and that the temperature variance is greater than the die temperature variation threshold and that the first die includes the defective temperature sensor.

15. The method of claim 12, further comprising executing a second defective temperature sensor scheme wherein:
the comparing comprises determining that temperatures of dies in the memory device are within the die temperature variation threshold and comparing a temperature of each die against an integrated circuit temperature, and
the determining comprises determining that there is a temperature variance between a die temperature and the integrated circuit temperature, that the temperature variance is greater than the die temperature variation threshold, and that a die with a temperature variance that is greater than the die temperature variation threshold includes the defective temperature sensor.

16. The method of claim 12, further comprising executing a third defective temperature sensor scheme wherein:
the comparing comprises determining that temperatures of dies in the memory device are within the die temperature variation threshold and comparing a temperature of each die against a temperature of an internal temperature sensor, and
the determining comprises determining that there is a temperature variance between a die temperature and the temperature of an internal temperature sensor, that the temperature variance is greater than the die temperature variation threshold, and that a die with a temperature variance that is greater than the die temperature variation threshold includes the defective temperature sensor.

17. The method of claim 12, further comprising executing a fourth defective temperature sensor scheme including checking the firmware to determine if the first die includes the defective temperature sensor.

18. A method in a storage device for identifying a die with a defective temperature sensor, the storage device includes a controller for executing the method comprising:
executing at least one defective temperature sensor scheme to obtain a temperature for a first die in a memory device;
at least one of:
comparing the first die temperature against temperatures of other dies in the memory device,
determining that temperatures of dies in the memory device are within a die temperature variation threshold and one of comparing a temperature of each die against an integrated circuit temperature and comparing a temperature of each die against a temperature of an internal temperature sensor, and
obtaining information from a firmware to determine if the first die includes the defective temperature sensor;
determining that the first die includes a defective temperature sensor if one of a temperature variance between the first die temperature and one of the integrated circuit temperature and the temperature of the internal temperature sensor is greater than the die temperature variation threshold and if the information from the firmware indicates that the first die include the defective sensor; and
excluding the first die temperature from thermal calculations.
